(19) United States
(12) Patent Application Publication
(10) Pub. No.: US 2025/0215283 A1
(43) Pub. Date: Jul. 3, 2025

(54) PRESSURE SENSITIVE ADHESIVE SHEET AND METHOD FOR PRODUCING ELECTRONIC COMPONENT OR SEMICONDUCTOR DEVICE

(71) Applicant: LINTEC Corporation, Tokyo (JP)

(72) Inventors: Tomofumi KATO, Tokyo (JP); Kenta NISHIJIMA, Tokyo (JP); Haruki SUEYOSHI, Tokyo (JP); Go ONISHI, Tokyo (JP); Takashi SUGINO, Tokyo (JP); Mutsumi MASUMOTO, Beppu-shi (JP)

(21) Appl. No.: 19/085,306

(22) Filed: Mar. 20, 2025

Related U.S. Application Data
(63) Continuation of application No. PCT/JP2023/034248, filed on Sep. 21, 2023.

(30) Foreign Application Priority Data
Sep. 22, 2022 (JP) 2022-151756
Sep. 22, 2022 (JP) 2022-151757
Mar. 31, 2023 (JP) 2023-058459
Mar. 31, 2023 (JP) 2023-058460
Mar. 31, 2023 (JP) 2023-058462
Mar. 31, 2023 (JP) 2023-058463

(51) Int. Cl. C09J 7/38; C09J 7/10; H01L 21/683

(52) U.S. Cl. CPC C09J 7/385; C09J 7/10; H01L 21/6836; C09J 2203/326; C09J 2301/20; C09J 2301/302; C09J 2301/414; C09J 2301/416

(57) ABSTRACT

A pressure sensitive adhesive sheet includes a pressure sensitive adhesive layer catching elements distant from a holding substrate. The pressure sensitive adhesive layer has unevenness on a surface and having a complex shear elastic modulus at 23° C. of 0.001 MPa or greater and 1.0 MPa or less.

### CROSS-REFERENCE TO RELATED APPLICATIONS

This application is a Continuation of International Patent Application No. PCT/JP2023/034248, filed Sep. 21, 2023, which claims the benefit of Japanese Patent Application No. 2022-151756 filed on Sep. 22, 2022, Japanese Patent Application No. 2022-151757 filed on Sep. 22, 2022, Japanese Patent Application No. 2023-058459 filed on Mar. 31, 2023, Japanese Patent Application No. 2023-058460 filed on Mar. 31, 2023, Japanese Patent Application No. 2023-058462 filed on Mar. 31, 2023, and Japanese Patent Application No. 2023-058463 filed on Mar. 31, 2023, all of which are hereby incorporated by reference herein in their entirety.

### BACKGROUND

### Field

The present invention relates to a pressure sensitive adhesive sheet and an electronic component or a semiconductor device.

### Description of the Related Art

Elements used in electronic components or semiconductor devices are often obtained by forming a large number of elements at once. For example, semiconductor chips are obtained by dicing a semiconductor wafer adhered to a pressure sensitive adhesive. When such a semiconductor chip is mounted on a semiconductor device, transfer of the semiconductor chip is often performed. For example, Japanese Patent Laid-Open No. 2021-141181 describes a method (laser lift-off method) of transferring a semiconductor chip by irradiating a semiconductor chip with a laser.

### SUMMARY

According to an embodiment of the present invention, a pressure sensitive adhesive sheet comprises: a pressure sensitive adhesive layer configured to catch elements distant from a holding substrate, wherein the pressure sensitive adhesive layer has unevenness on a surface and has a complex shear elastic modulus at 23° C. of 0.001 MPa or greater and 1.0 MPa or less.

According to another embodiment of the present invention, a method for producing an electronic component or a semiconductor device comprises: separating an element adhered to a holding substrate from the holding substrate by an external stimulus; allowing a pressure sensitive adhesive layer to hold the element by pressing the element separated from the holding substrate against a pressure sensitive adhesive sheet and deforming a plurality of protruded portions on a surface of the pressure sensitive adhesive layer, wherein the pressure sensitive adhesive sheet comprises the pressure sensitive adhesive layer configured to catch elements distant from the holding substrate, the pressure sensitive adhesive layer has unevenness on the surface and has a complex shear elastic modulus at 23° C. of 0.001 MPa or greater and 1.0 MPa or less, each of the plurality of protruded portions has a boundary defined by a recessed portion, and the plurality of protruded portions are separated from each other; and promoting separation of the element from the pressure sensitive adhesive sheet by allowing the plurality of protruded portions deformed to be recovered to a protruded shape by an external stimulus.

Further features of the present invention will become apparent from the following description of exemplary embodiments (with reference to the attached drawings).

### BRIEF DESCRIPTION OF THE DRAWINGS

FIG. 1 is a schematic view of a pressure sensitive adhesive sheet according to an embodiment.

FIG. 2A is a top view of an example of unevenness included in a pressure sensitive adhesive sheet.

FIG. 2B is a top view of an example of unevenness included in a pressure sensitive adhesive sheet.

FIG. 2C is a top view of an example of unevenness included in a pressure sensitive adhesive sheet.

FIG. 3A is a cross-sectional view of an example of unevenness included in a pressure sensitive adhesive sheet.

FIG. 3B is a cross-sectional view of an example of unevenness included in a pressure sensitive adhesive sheet.

FIG. 3C is a cross-sectional view of an example of unevenness included in a pressure sensitive adhesive sheet.

FIG. 4 is a flow chart of a method for producing an electronic component or a semiconductor device according to an embodiment.

FIG. 5A is a schematic view explaining separation and catching of elements.

FIG. 5B is a schematic view explaining separation and catching of elements.

FIG. 5C is a schematic view explaining separation and catching of elements.

FIG. 6A is a schematic view explaining holding of elements.

FIG. 6B is a schematic view explaining holding of elements.

FIG. 7A is a schematic view explaining recovery of protruded portions.

FIG. 7B is a schematic view explaining recovery of protruded portions.

FIG. 8A is a schematic view of a pressure sensitive adhesive sheet placed on an expander.

FIG. 8B is a schematic view of a pressure sensitive adhesive sheet placed on an expander.

### DESCRIPTION OF THE EMBODIMENTS

Embodiments will be described in detail below with reference to the attached drawings. Note that the following embodiments are not intended to limit the scope of the claimed invention, and the invention does not necessarily require all combinations of features described in the embodiments. Two or more of the multiple features described in the embodiments may be combined as appropriate. Furthermore, the same reference numerals are given to the same or similar configurations, and redundant description thereof is omitted.

When an element is transferred from a substrate before the transfer to a substrate after the transfer, the element is held on the substrate after the transfer. In recent years, miniaturization of semiconductor devices and elements has been made. Because displacement of transfer position can obstruct the miniaturization, the element is required to be held firmly on the substrate after the transfer. Meanwhile, the element held on the substrate after the transfer is picked up from the substrate after the transfer after predetermined treatment. Thus, the element to which the predetermined treatment has been performed is required to be weakly held on the substrate after the transfer so that the element can be picked up easily from the substrate after the transfer.

As a result of diligent study, the inventors of the present invention found that the problems described above can be solved by providing unevenness with a predetermined complex shear elastic modulus on a surface of a pressure sensitive adhesive sheet holding an element. The inventors further conducted various study to achieve the present invention.

An embodiment of the present invention can provide a pressure sensitive adhesive sheet that can change capability of holding the element.

### Definition

In the present description, the mass average molecular weight (Mw) and the number average molecular weight (Mn) are values measured by a size exclusion chromatography method calibrated with a polystyrene standard, and more specifically, are values measured based on JIS K 7252-1:2016. In addition, in the present description, “(meth)acrylic acid” is a term referring to both “acrylic acid” and “methacrylic acid”, and the same shall apply to other similar terms.

In the present description, “electronic component” includes all components used in electronics, electrical engineering, and the like, and includes all components constituting electronic devices. “Electronic component” may be made of a semiconductor, an electric conductor, and/or an insulator or may be made of a combination of these. Examples of “electronic component” include active components (that are mainly made of semiconductors; examples thereof include a transistor, IC, LSI, VLSI, a diode, a light emitting diode, a thyristor, a 3-terminal regulator, and an image sensor), passive elements (examples thereof include a resistor, a capacitor, a speaker, a coil, a transformer, a power transformer, a relay, a piezoelectric element, a quartz crystal unit, a ceramic resonator, and a varistor), and structural components (examples thereof include a wiring component, a printed-circuit board, a connector, and a switch). Furthermore, in the present specification, “semiconductor device” refers to devices that can function by utilizing semiconducting properties in general, such devices being used for processors, memories, sensors, and the like. Examples of “semiconductor device” include a micro LED, a mini LED, a power device, micro-electromechanical systems (MEMS), and a controller chip.

In the present specification, a case where one or more lower limit values and one or more upper limit values are described for a numerical range (e.g., range of content) can be understood as a description of a combination of a lower limit value and an upper limit value that are freely chosen therefrom. For example, the description of 1 or greater, 2 or greater, and 3 or greater, and 9 or less, 8 or less, and 7 or less clearly means that the numerical range may be any one of 1 or greater and 9 or less, 1 or greater and 8 or less, 1 or greater and 7 or less, 2 or greater and 9 or less, 2 or greater and 8 or less, 2 or greater and 7 or less, 3 or greater and 9 or less, 3 or greater and 8 or less, or 3 or greater and 7 or less.

### Pressure Sensitive Adhesive Sheet According to Present Embodiment

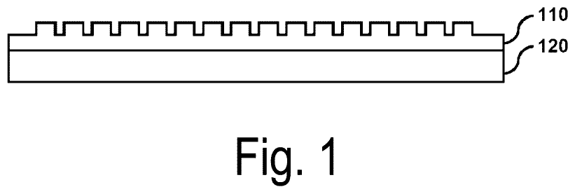

The pressure sensitive adhesive sheet according to the present embodiment includes a pressure sensitive adhesive layer catching an element distant from a holding substrate, and the pressure sensitive adhesive layer includes unevenness on its surface. FIG. 1 is a schematic view of a pressure sensitive adhesive sheet according to an embodiment. In an embodiment, the pressure sensitive adhesive sheet may include a pressure sensitive adhesive layer 110 and a base material 120. The pressure sensitive adhesive sheet is not required to include a base material 120. For example, the pressure sensitive adhesive sheet may be made only of a pressure sensitive adhesive layer 110. In this case, a pressure sensitive adhesive layer 110 having high supportability can be used. The components of the pressure sensitive adhesive sheet will be described below.

### Pressure Sensitive Adhesive Layer

The pressure sensitive adhesive layer 110 according to the present embodiment is a layer exhibiting pressure sensitive adhesion and may contain a resin. As described above, a surface of the pressure sensitive adhesive layer 110 has unevenness. Note that the pressure sensitive adhesive sheet may include two or more pressure sensitive adhesive layers 110. For example, the pressure sensitive adhesive sheet may include a laminate of one type or two or more types of pressure sensitive adhesive layer 110.

### Complex Shear Elastic Modulus

The pressure sensitive adhesive layer 110 according to the present embodiment has a complex shear elastic modulus at 23° C. of 0.001 MPa or greater and 1.0 MPa or less. The complex shear elastic modulus can be preferably 1.0 MPa or less, more preferably 0.8 MPa or less, even more preferably 0.6 MPa or less, and particularly preferably 0.3 MPa or less. By this, when an element is held on the pressure sensitive adhesive sheet, the protruded portion can be pressed, deformed, and squashed by the element. Furthermore, as the protruded portion is deformed and squashed, the recessed portion of the pressure sensitive adhesive layer 110 rises, and the protruded portion and the recessed portion are brought into contact with the element. By this, because the element and the pressure sensitive adhesive layer 110 are in contact in a plane, the element is held firmly on the pressure sensitive adhesive layer 110.

The complex shear elastic modulus can be preferably 0.001 MPa or greater, more preferably 0.01 MPa or greater, even more preferably 0.05 MPa or greater, and particularly preferably 0.1 MPa or greater. By this, when the element is picked up from the pressure sensitive adhesive sheet, by applying an external stimulus to the pressure sensitive adhesive sheet, the deformed protruded portion can recover a protruded shape. Furthermore, as the deformed protruded portion recovers the protruded shape, the deformed recessed portion recovers a recessed shape, and the protruded portion and the element are in contact at a point. Thus, the element is weakly held on the pressure sensitive adhesive layer 110. As a result, the element can be easily picked up from the pressure sensitive adhesive sheet.

Furthermore, the range of the complex shear elastic modulus can be preferably 0.001 MPa or greater and 1.0 MPa or less, more preferably 0.01 MPa or greater and 0.8 MPa or less, even more preferably 0.05 MPa or greater and 0.6 MPa or less, and particularly preferably 0.1 MPa or greater and 0.3 MPa or less. By this, the pressure sensitive adhesive sheet according to the present embodiment can vary the capability of holding the element.

The complex shear elastic modulus of the pressure sensitive adhesive layer 110 can be confirmed as follows, for example. By producing a sample having a diameter of 8 mm and a thickness of 1 mm and using a viscoelasticity measuring instrument, a complex shear elastic modulus of a sample at 23° C. is measured at a frequency of 1 Hz using a torsional shear method, and thus the complex shear elastic modulus of the pressure sensitive adhesive layer 110 can be measured. A more specific method of measuring the complex shear elastic modulus will be described in Examples.

### Shape

A surface of the pressure sensitive adhesive layer 110 has unevenness. Holding capability between the element and the pressure sensitive adhesive layer 110 can be varied when the surface of the pressure sensitive adhesive layer 110 includes unevenness having a predetermined complex shear elastic modulus. Thus, specific forms of unevenness included on the surface of the pressure sensitive adhesive layer 110 are not limited.

In an embodiment, the pressure sensitive adhesive layer 110 includes a plurality of protruded portions that are separated from each other, and each of the plurality of protruded portions has a boundary defined by a recessed portion, on the surface of the pressure sensitive adhesive layer 110. Each of the plurality of protruded portions may be separated by a recessed portion continuous on the whole pressure sensitive adhesive layer 110. By providing such a continuous recessed portion around the protruded portions, the capability of holding the element can be enhanced.

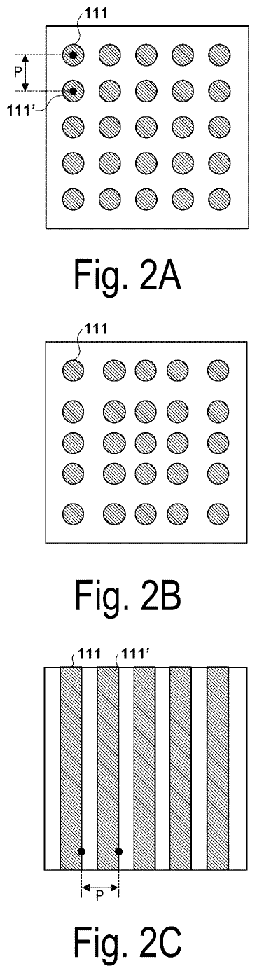

Meanwhile, the gas compressed in between the element and the pressure sensitive adhesive layer 110 caused when the element gets closer to the pressure sensitive adhesive layer 110 is allowed to escape to a recessed portion of the pressure sensitive adhesive sheet. Thus, the pressure caused between the element and the pressure sensitive adhesive layer 110 can be relaxed. Thus, displacement of holding position of the element on the pressure sensitive adhesive sheet due to the pressure caused between the element and the pressure sensitive adhesive layer 110 can be suppressed. In an embodiment, a recessed portion positioned around each of the plurality of protruded portions continues to edges of the pressure sensitive adhesive layer 110. By providing a recessed portion continuing to edges of the pressure sensitive adhesive layer 110 as described above, a gas compressed between an element and the protruded portion of the pressure sensitive adhesive layer 110 can be allowed to escape outside of the element efficiently. FIG. 2A to FIG. 2C are top views illustrating forms of such pressure sensitive adhesive layers 110.

As illustrated in FIG. 2A, the protruded portions 111 may be regularly arranged on the surface of the pressure sensitive adhesive layer 110. Regular arrangement of the protruded portions 111 means that the protruded portions 111 are arranged in a straight line at a regular interval. Furthermore, as illustrated in FIG. 2B, the protruded portions 111 may be arranged in a manner that the spacing therebetween varies regularly. In the example of FIG. 2B, the spacing between the protruded portions 111 is smaller in a central part of the pressure sensitive adhesive sheet, and the spacing between the protruded portions 111 is longer in a peripheral part of the pressure sensitive adhesive sheet. According to such configuration, a compressed gas can be effectively allowed to escape from the peripheral part of the element through a wider recessed portion while the holding capability of the pressure sensitive adhesive sheet is enhanced. Furthermore, the protruded portions 111 may be arranged irregularly.

FIG. 2C is a top view illustrating another form of the pressure sensitive adhesive layer 110. As illustrated in FIG. 2C, the surface of the pressure sensitive adhesive layer 110 may have protruded portions 111 in a stripe form. In FIG. 2C, linear protruded portions 111 having a fixed width are arranged at a regular interval. Meanwhile, similarly to FIG. 2B, widths or spacing of the linear protruded portions 111 may vary regularly, or the linear protruded portions 111 may be arranged irregularly.

Note that, similarly to FIG. 2B, the smallest spacing among all spacing of the protruded portions 111 in a central part of the pressure sensitive adhesive sheet may be shorter than the smallest spacing among all spacing of the protruded portions 111 in the peripheral part of the pressure sensitive adhesive sheet. Note that, for example, the central part is a circular region having ¼ area of the pressure sensitive adhesive sheet and having a center at the center of gravity of the pressure sensitive adhesive sheet. For example, the peripheral part is all region except the central part of the pressure sensitive adhesive sheet.

From the viewpoint of adjusting the holding capability, a pitch P of the protruded portions 111 is preferably 1 μm or greater, more preferably 5 μm or greater, even more preferably 10 μm or greater, and particularly preferably 15 μm or greater. Meanwhile, from the viewpoint of enhancing the holding power by increasing the contact area of the pressure sensitive adhesive layer 110 and the element, this pitch is preferably 100 μm or less, more preferably 75 μm or less, even more preferably 50 μm or less, yet even more preferably 35 μm or less, and particularly preferably 25 μm or less. Note that the pitch of the protruded portions 111 means a distance between a center point of one freely chosen protruded portion 111 and a center point of a protruded portion 111 that is the closest to the chosen protruded portion 111. For example, in the case of FIG. 2A, the pitch of the protruded portions 111 is a distance between a center point of the protruded portion 111 in the straight line, where protruded portions 111 are arranged at a regular interval, and a center point of another protruded portion 111′ that is the closest to the protruded portion 111. In a case where the plurality of the protruded portions 111 is arranged in a straight line, the pitch refers to a distance between center points of protruded portions that are arranged with the shortest pitch in the straight line. Furthermore, for example, in a case where a center point of a protruded portion is difficult to be identified due to a long and narrow form as illustrated in FIG. 2C, the spacing refers to a distance from a boundary of the protruded portion 111 to a boundary of the same side of the closest another protruded portion 111′.

The specific form of the protruded portion 111 is not particularly limited. For example, the protruded portion 111 may have a pillar (column) form. As a specific example, the protruded portion 111 may have a circular cylindrical shape or may have a prism shape. Furthermore, the protruded portion 111 may be extended in a line form as described above or may be extended in a curve form, such as a wave form. Furthermore, these protruded portions 111 may be tapered.

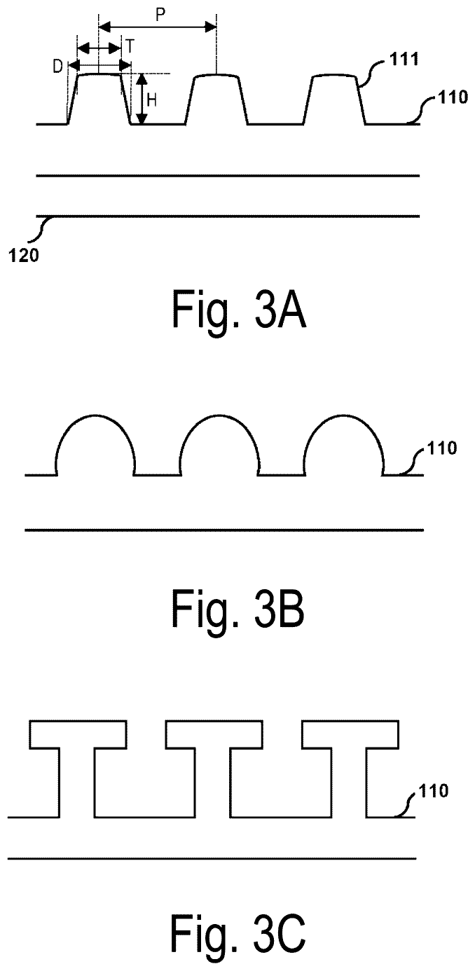

FIG. 3A illustrates a cross-sectional view seen vertically with respect to a surface of a pressure sensitive adhesive layer 110 passing through a protruded portion 111 of the pressure sensitive adhesive layer 110 according to an embodiment. The protruded portion 111 illustrated in FIG. 3A is provided with a taper, that is, the protruded portion 111 is tapered. As illustrated in FIG. 3A, a surface of the pressure sensitive adhesive layer 110 may include a flat recessed portion, and protruded portions 111 that protrude from the recessed portion. As described above, a plurality of protruded portions 111, which are separated from each other included in the pressure sensitive adhesive layer 110, may have boundaries defined by the recessed portion.

Furthermore, as illustrated in FIG. 3B, the tip of the protruded portion 111 may be semispherical or a curved face similar to a part of a sphere. According to such a configuration, impact at the time of contact of the element separated from a holding substrate and the pressure sensitive adhesive layer 110 is more relaxed, catching of the element by the pressure sensitive adhesive layer 110 without displacement is facilitated. Meanwhile, the tip of the protruded portion may be a flat face.

Furthermore, the protruded portion 111 may be in a T-shape as illustrated in FIG. 3C. In another example, the protruded portion 111 may be in a form having a plurality of particles aggregated, a mushroom form, a form of lotus leaf surface, or a needle form. As other examples, the surface of the pressure sensitive adhesive layer 110 may be a rough surface or fibrous surface, and these surfaces can be said to have unevenness.

The width or size of each of the protruded portions 111 is a width or size of a base part, not a tip part, and the width or size thereof is preferably 1 μm or greater, more preferably 2 μm or greater, even more preferably 5 μm or greater, and particularly preferably 10 μm or greater. Meanwhile, the width or size thereof is preferably 100 μm or less, more preferably 50 μm or less, even more preferably 30 μm or less, and particularly preferably 20 μm or less. By this, the capability of holding an element can be varied. Note that the width and the size of a protruded portion 111 respectively mean a minimum distance and a maximum distance between two parallel lines that are in contact with both sides of the protruded portion 111 at a surface of the recessed portion (represented as D in FIG. 3A).

Furthermore, the area of each of the protruded portions 111 is preferably 10 μm² or greater, more preferably 20 μm² or greater, and even more preferably 30 μm² or greater. Meanwhile, the area of each of the protruded portions 111 is preferably 2000 μm² or less, more preferably 1000 μm² or less, and even more preferably 500 μm² or less. By this, the capability of holding an element can be varied. Note that the area of the protruded portion 111 means an area of a part protruded from the surface of the recessed portion (area of a circle having a diameter D in the case of FIG. 3A).

Furthermore, the height of each of the protruded portions 111 is preferably 1 μm or greater, more preferably 3 μm or greater, and even more preferably 5 μm or greater. Meanwhile, the height of each of the protruded portions 111 is preferably 20 μm or less, more preferably 15 μm or less, and even more preferably 10 μm or less. By this, the capability of holding an element can be varied. Note that the height of the protruded portion 111 is represented as H in FIG. 3A.

Furthermore, the area of each of the protruded portions 111 with respect to the area of the pressure sensitive adhesive layer 110 is preferably 1% or greater, more preferably 5% or greater, even more preferably 10% or greater, yet even more preferably 18% or greater, and particularly preferably 40% or greater. Meanwhile, the area of each of the protruded portions with respect to the area of the pressure sensitive adhesive layer 110 is preferably 95% or less, more preferably 75% or less, and even more preferably 60% or less. By this, the capability of holding an element can be varied.

The unevenness included in the pressure sensitive adhesive layer 110 may be designed based on a form of an element held by the pressure sensitive adhesive sheet. For example, a ratio of an adhesion area between the pressure sensitive adhesive layer 110 and one element with respect to an area of the one element is preferably 1% or greater, more preferably 2% or greater, even more preferably 3% or greater, yet even more preferably 4% or greater, yet even more preferably 5% or greater, yet even more preferably 7% or greater, and particularly preferably 10% or greater, with respect to 100% area of the one element. Meanwhile, the ratio of the adhesion area between the pressure sensitive adhesive layer 110 and one element with respect to an area of the one element is preferably 95% or less, more preferably 70% or less, even more preferably 50% or less, and particularly preferably 30% or less. In the case of FIG. 3A, the adhesion area corresponds to an area of a circle having a diameter T. Note that, in a case where a catching position of an element is displaced on the pressure sensitive adhesive sheet, the adhesion area may vary. In this case, the ratio of adhesion area may fall within the range described above regardless of the catching position of the element.

Composition of Pressure Sensitive Adhesive Layer (Pressure Sensitive Adhesive Composition)

The pressure sensitive adhesive composition constituting the pressure sensitive adhesive layer 110 contains a resin. Examples of the resin contained in the pressure sensitive adhesive composition include rubber-based resins, such as polyisobutylene-based resins, polybutadiene-based resins, and styrene-butadiene-based resins, acrylic resins, urethane-based resins, polyester-based resins, olefin-based resins, silicone-based resins, and polyvinyl ether-based resins. Furthermore, the pressure sensitive adhesive layer may have heat resistance, and examples of a raw material of the pressure sensitive adhesive layer having such heat resistance include polyimide-based resins and silicone-based resins. The pressure sensitive adhesive composition constituting the pressure sensitive adhesive layer 110 may contain a copolymer containing two or more types of constitutional units. The form of such a copolymer is not particularly limited. The copolymer may be any of a block copolymer, a random copolymer, an alternating copolymer, or a graft copolymer. Furthermore, the resin contained in the pressure sensitive adhesive composition constituting the pressure sensitive adhesive layer 110 may be made of one type of resin or may be made of two or more types of resins.

The resin contained in the pressure sensitive adhesive composition constituting the pressure sensitive adhesive layer 110 can be a pressure sensitive adhesive resin having pressure sensitive adhesion by itself. Furthermore, the resin can be a polymer having a mass average molecular weight (Mw) of 10000 or greater. From the viewpoint of enhancing adhesive strength, the mass average molecular weight (Mw) of the resin is preferably 10000 or greater, more preferably 70000 or greater, and even more preferably 140000 or greater. Furthermore, from the viewpoint of suppressing the complex shear elastic modulus to a predetermined value or less, the mass average molecular weight (Mw) of the resin is preferably 2000000 or less, more preferably 1200000 or less, and even more preferably 900000 or less. Furthermore, from the viewpoint of enhancing adhesive strength, the number average molecular weight (Mn) of the resin is preferably 10000 or greater, more preferably 50000 or greater, and even more preferably 100000 or greater. Furthermore, from the viewpoint of suppressing the complex shear elastic modulus to a predetermined value or less, the number average molecular weight (Mn) of the resin is preferably 2000000 or less, more preferably 1000000 or less, and even more preferably 700000 or less. In a case where the pressure sensitive adhesive layer 110 contains a resin derived from an energy ray-curable resin as described below, the mass average molecular weight (Mw) and the number average molecular weight (Mn) refer to a mass average molecular weight (Mw) and a number average molecular weight (Mn) before cross-linking reaction caused by provided energy.

Furthermore, the glass transition temperature (Tg) of the resin is preferably −75° C. or higher, and more preferably −70° C. or higher, and preferably −10° C. or lower, and more preferably −20° C. or lower. When the Tg is in the range described above, the complex shear elastic modulus of the resulting pressure sensitive adhesive layer can be set to the range described below.

The amount of the resin with respect to the entire amount of components constituting the pressure sensitive adhesive composition forming the pressure sensitive adhesive layer 110 can be appropriately set based on the adhesive strength of a desired pressure sensitive adhesive layer 110 and the complex shear elastic modulus, and is preferably 30 mass % or greater, more preferably 40 mass % or greater, even more preferably 50 mass % or greater, yet even more preferably 55 mass % or greater, and particularly preferably 60 mass % or greater, and preferably 99.99 mass % or less, more preferably 99.95 mass % or less, and even more preferably 99.90 mass % or less.

### Thermoplastic Resin

In an embodiment, the resin contained in the pressure sensitive adhesive composition forming the pressure sensitive adhesive layer 110 may contain a thermoplastic resin. That is, the pressure sensitive adhesive layer 110 may be made of a thermoplastic resin. In a case where a thermoplastic resin is used, formation of unevenness on the pressure sensitive adhesive layer 110 is facilitated by softening a resin by heating, and unevenness shapes formed by cooling of the resin can be easily maintained. Examples of the thermoplastic resin include rubber-based resins, acrylic resins, urethane-based resins, and olefin-based resins. Examples thereof include polybutadiene-based thermoplastic elastomers using butadiene as a monomer, styrene-based thermoplastic elastomers using styrene as a monomer, and acrylic thermoplastic elastomers using a (meth)acrylate as a monomer.

### Acrylic Resin (A)

In an embodiment, the thermoplastic resin can be an acrylic resin (A). From the viewpoint of enhancing adhesive strength, the mass average molecular weight (Mw) of the acrylic resin (A) is preferably 10000 or greater, more preferably 100000 or greater, and even more preferably 500000 or greater. Furthermore, from the viewpoint of suppressing the complex shear elastic modulus to a predetermined value or less, the mass average molecular weight (Mw) is preferably 2000000 or less, more preferably 1500000 or less, and even more preferably 1000000 or less.

The glass transition temperature (Tg) of the acrylic resin (A) is preferably-75° C. or higher, and more preferably −70° C. or higher, and preferably 5° C. or lower, more preferably −25° C. or lower, and even more preferably −55° C. or lower. When the Tg is in the range described above, the complex shear elastic modulus of the resulting pressure sensitive adhesive can be set to the range.

In the case of the acrylic resin (A) having two or more constitutional units, the glass transition temperature (Tg) of the acrylic resin (A) can be calculated using Fox equation. For the Tg of the monomer deriving the constitutional unit used here, a value described in Polymer Data Handbook or Pressure Sensitive Adhesion Handbook can be used.

Examples of the (meth)acrylate constituting the acrylic resin (A) include alkyl (meth)acrylates in which the alkyl group constituting the alkyl ester has a chain structure having from 1 to 18 carbons, such as methyl (meth)acrylate, ethyl (meth)acrylate, n-propyl (meth)acrylate, isopropyl (meth)acrylate, n-butyl (meth)acrylate, isobutyl (meth)acrylate, sec-butyl (meth)acrylate, tert-butyl (meth)acrylate, pentyl (meth)acrylate, hexyl (meth)acrylate, heptyl (meth)acrylate, 2-ethylhexyl (meth)acrylate, isooctyl (meth)acrylate, n-octyl (meth)acrylate, n-nonyl (meth)acrylate, isononyl (meth)acrylate, decyl (meth)acrylate, undecyl (meth)acrylate, lauryl (meth)acrylate, tridecyl (meth)acrylate, myristyl (meth)acrylate, pentadecyl (meth)acrylate, palmityl (meth)acrylate, heptadecyl (meth)acrylate, and stearyl (meth)acrylate; cycloalkyl (meth)acrylates, such as isobornyl (meth)acrylate and dicyclopentanyl (meth)acrylate; aralkyl (meth)acrylates, such as benzyl (meth)acrylate; cycloalkenyl (meth)acrylates, such as dicyclopentenyl (meth)acrylate; cycloalkenyloxyalkyl (meth)acrylates, such as dicyclopentenyloxyethyl (meth)acrylate; (meth)acrylic imide; glycidyl group-containing (meth)acrylates, such as glycidyl (meth)acrylate; hydroxy group-containing (meth)acrylates, such as hydroxymethyl (meth)acrylate, 2-hydroxyethyl (meth)acrylate, 2-hydroxypropyl (meth)acrylate, 3-hydroxypropyl (meth)acrylate, 2-hydroxybutyl (meth)acrylate, 3-hydroxybutyl (meth)acrylate, and 4-hydroxybutyl (meth)acrylate; and substituted amino group-containing (meth)acrylates, such as N-methylaminoethyl (meth)acrylate. Note that the “substituted amino group” means a group having a structure in which one or two hydrogen atoms of an amino group are substituted with a group other than hydrogen atoms.

The acrylic resin (A) may be a resin obtained by copolymerization of one type or two or more types of monomers selected from, for example, (meth)acrylic acid, itaconic acid, vinyl acetate, acrylonitrile, styrene, and N-methylolacrylamide in addition to (meth)acrylates.

The acrylic resin (A) may be constituted of only one type or two or more types of monomers. When two or more types of monomers constitute the acrylic resin (A), their combination and ratio can be freely chosen.

Besides the hydroxy group, the acrylic resin (A) may have a functional group, such as a vinyl group, a (meth)acryloyl group, an amino group, a carboxy group, and an isocyanate group, that can be bonded to another compound. These functional groups such as the hydroxy group of the acrylic resin (A) may be bonded to another compound via a cross-linking agent (C) described below or may be directly bonded to another compound without the cross-linking agent (C).

The amount of the acrylic resin (A) with respect to the entire amount of the resin of the pressure sensitive adhesive composition can be appropriately set based on the adhesive strength of a desired pressure sensitive adhesive layer 110 and the complex shear elastic modulus, and is preferably 0 mass % or greater, more preferably 10 mass % or greater, even more preferably 20 mass % or greater, and particularly preferably 50 mass % or greater, and preferably 100 mass % or less, and more preferably 95 mass % or less.

### Energy Ray-Curable Resin (B)

In an embodiment, the resin contained in the pressure sensitive adhesive composition forming the pressure sensitive adhesive layer 110 may contain an energy ray-curable resin (B). “Energy ray-curable” means a property of being cured by irradiation with an energy ray, and the energy ray-curable resin (B) refers to a resin that is cured by irradiation with an energy ray. Furthermore, “energy ray” means an electromagnetic wave or a charged particle beam having an energy quantum, and examples include ultraviolet rays, radiation, and electron beams. The ultraviolet rays can be irradiated by using, for example, an electrodeless lamp, a high-pressure mercury lamp, a metal halide lamp, or a UV-LED as an ultraviolet ray source. The electron beam can be generated by an electron beam accelerator or the like and irradiated. Furthermore, “energy ray-polymerizable” refers to a property of being polymerized by irradiation with energy rays.

In a case where such an energy ray-curable resin (B) is used, by providing an energy after unevenness is formed on a resin (e.g., irradiation with an energy ray), the formed unevenness shape can be easily maintained.

As the energy ray-curable resin (B), a monomer, an oligomer, and a polymer, to which a polymerizable functional group has been introduced can be used. The polymerizable functional group is a functional group that is cross-linked when energy is provided (e.g., irradiation of an energy ray). Examples of the polymerizable functional group include a vinyl group, an alkenyl group such as an allyl group, a (meth)acryloyl group, an oxetanyl group, and an epoxy group.

From the viewpoint of enhancing adhesive strength, the mass average molecular weight (Mw) of the energy ray-curable resin (B) is preferably 100 or greater, and more preferably 150 or greater. Furthermore, from the viewpoint of suppressing the complex shear elastic modulus to a predetermined value or less, the mass average molecular weight (Mw) is preferably 2000000 or less, more preferably 1000000 or less, and even more preferably 200000 or less.

When a monomer or an oligomer is used as the energy ray-curable resin (B), the number average molecular weight (Mn) of the energy ray-curable resin (B) is preferably 100 or greater, and more preferably 150 or greater, from the viewpoint of polymerizability. Furthermore, from the viewpoint of suppressing the complex shear elastic modulus to a predetermined value or less, the number average molecular weight (Mn) is preferably 5000 or less, more preferably 1000 or less, and even more preferably 500 or less.

When a polymer is used as the energy ray-curable resin (B), the mass average molecular weight (Mw) of the energy ray-curable resin (B) is preferably 10000 or greater, more preferably 50000 or greater, and even more preferably 100000 or greater, from the viewpoint of enhancing adhesive strength. Furthermore, from the viewpoint of suppressing the complex shear elastic modulus to a predetermined value or less, the mass average molecular weight (Mw) is preferably 2000000 or less, more preferably 500000 or less, and even more preferably 300000 or less.

The average value of the number of the polymerizable functional groups per molecule in the energy ray-curable resin (B) is preferably 1.5 or greater, and more preferably 2 or greater, from the viewpoint of facilitating maintenance of unevenness shapes of the pressure sensitive adhesive layer. Meanwhile, from the viewpoint of enhancing pressure sensitive adhesion and flexibility of the pressure sensitive adhesive layer, this average value is preferably 20 or less, more preferably 15 or less, and even more preferably 10 or less.

In an embodiment, as the energy ray-curable resin (B), a monomer or oligomer having a polymerizable functional group can be used. Examples of the energy ray-curable compound include polyvalent (meth)acrylate monomers, such as glycerin di (meth)acrylate, glycerin tri (meth)acrylate, 1,4-butylene glycol di (meth)acrylate, 1,6-hexanediol (meth)acrylate, trimethylolpropane tri (meth)acrylate, pentaerythritol (meth)acrylate, pentaerythritol tetra (meth)acrylate, dipentaerythritol hexa (meth)acrylate, and tricyclodecane dimethanol di (meth)acrylate; urethane (meth)acrylate; polyester (meth)acrylate; polyether (meth)acrylate; and epoxy (meth)acrylate. Among these, from the viewpoint of maintaining the formed unevenness shape, glycerin di (meth)acrylate, glycerin tri (meth)acrylate, and tricyclodecane dimethanol di (meth)acrylate are preferred.

In an embodiment, as the energy ray-curable resin (B), a diene-based rubber made of a polymer having a polymerizable functional group in a main chain terminal and/or a side chain can be used. The diene-based rubber refers to a rubber-like polymer having a double bond in a polymer main chain. Specific examples of the diene-based rubber include a polymer using butadiene or isoprene as a monomer (that is, containing a butenediyl group or a pentenediyl group as a constitutional unit). In an embodiment, examples of the energy ray-curable resin (B) include a polybutadiene resin (PB resin), a styrene-butadiene-styrene block copolymer (SBS resin), and a styrene-isoprene-styrene block copolymer.

The amount of the energy ray-curable resin (B) with respect to the entire amount of the resin of the pressure sensitive adhesive composition can be appropriately set based on the adhesive strength of a desired pressure sensitive adhesive layer 110 and the complex shear elastic modulus, and is preferably 0 mass % or greater, more preferably 10 mass % or greater, even more preferably 20 mass % or greater, and particularly preferably 50 mass % or greater, and preferably 100 mass % or less, more preferably 95 mass % or less, even more preferably 80 mass % or less, and particularly preferably 60 mass % or less.

Furthermore, in an embodiment, the pressure sensitive adhesive composition may contain an acrylic resin (A) and an energy ray-curable resin (B). The relationship between the content of the acrylic resin (A) and the content of the energy ray-curable resin (B) can be appropriately set based on the adhesive strength of a desired pressure sensitive adhesive layer 110 and the complex shear elastic modulus. In an embodiment, the content of the acrylic resin (A) in the total content of the acrylic resin (A) and the energy ray-curable resin (B) is preferably 0 mass % or greater, more preferably 10 mass % or greater, even more preferably 20 mass % or greater, and particularly preferably 50 mass % or greater, and preferably 100 mass % or less, and more preferably 95 mass % or less.

The pressure sensitive adhesive composition constituting the pressure sensitive adhesive layer 110 may contain a component other than the resin. For example, the pressure sensitive adhesive composition may contain one or more selected from a cross-linking agent (C), a photopolymerization initiator (D), an antioxidant (E), or other additives.

### Cross-Linking Agent (C)

The pressure sensitive adhesive composition may contain a cross-linking agent (C) for bonding and cross-linking a functional group of the resin with another compound. Examples of the cross-linking agent (C) include isocyanate-based cross-linking agents (cross-linking agents having an isocyanate group) such as tolylene diisocyanate, hexamethylene diisocyanate, and xylylene diisocyanate, and adducts of these diisocyanates; epoxy-based cross-linking agents (cross-linking agents having a glycidyl group) such as ethylene glycol glycidyl ether; aziridine-based cross-linking agents (cross-linking agents having an aziridinyl group) such as hexa [1-(2-methyl)-aziridinyl]triphosphatriazine; metal chelate-based cross-linking agents (cross-linking agents having a metal chelate structure) such as aluminum chelates; and isocyanurate-based cross-linking agents (cross-linking agents having an isocyanuric acid backbone).

The pressure sensitive adhesive composition may contain one type of cross-linking agent or may contain two or more types of cross-linking agents. The content of the cross-linking agent (C) in the pressure sensitive adhesive composition is preferably 0.01 mass % or greater, more preferably 0.1 mass % or greater, and even more preferably 1 mass % or greater, and preferably 5 mass % or less, more preferably 4 mass % or less, and even more preferably 2 mass % or less, from the viewpoint of performing a cross-linking reaction properly.

### Photopolymerization Initiator (D)

The pressure sensitive adhesive composition may contain a photopolymerization initiator (D) initiating a cross-linking reaction upon energy being provided (e.g., irradiation of an energy ray). In a case where the pressure sensitive adhesive composition contains an energy ray-curable resin (B), by allowing the pressure sensitive adhesive layer 110 to contain the photopolymerization initiator (D), a cross-linking reaction proceeds even when relatively low energy energy is provided.

Examples of the photopolymerization initiator (D) include 1-hydroxycyclohexyl phenyl ketone, benzoin, benzoin methyl ether, benzoin ethyl ether, benzoin propyl ether, benzyl phenyl sulfide, tetramethylthiuram monosulfide, azobisisobutyronitrile, dibenzyl, diacetyl, 8-chloroanthraquinone, and bis(2,4,6-trimethylbenzoyl)phenylphosphine oxide.

The pressure sensitive adhesive composition may contain one type of polymerization initiator or may contain two or more types of polymerization initiators. The content of the photopolymerization initiator (D) in the pressure sensitive adhesive composition is preferably 0.01 mass % or greater, more preferably 0.1 mass % or greater, and even more preferably 1 mass % or greater, and preferably 10 mass % or less, more preferably 5 mass % or less, and even more preferably 2 mass % or less.

### Antioxidant (E)

The pressure sensitive adhesive composition may contain an antioxidant (E). Examples of the antioxidant (E) include a phenol-based antioxidant such as a hindered phenol-based compound, an aromatic amine-based antioxidant, a sulfur-based antioxidant, or a phosphorus-based antioxidant such as a phosphate-based compound.

Furthermore, the pressure sensitive adhesive composition constituting the pressure sensitive adhesive layer 110 may contain one or more selected from a UV absorber, a light stabilizer, a resin stabilizer, a filler, a pigment, an extender, a softener, or the like.

### Base Material

The base material 120 included in the pressure sensitive adhesive sheet according to the present embodiment functions as a support carrying the pressure sensitive adhesive layer 110. The type of base material 120 is not particularly limited and may be a hard base material or a flexible base material. From the viewpoints of enhancing cushioning characteristics at the time of catching an element, facilitating installment to another member, enhancing releasability, facilitating lamination, or capability of being formed into a roll form, the base material 120 can be a flexible base material. As the base material 120, for example, a resin film can be used.

The resin film is a film containing a resin-based material as a main material, and may be made of a resin material or may contain an additive in addition to the resin material. The resin film may have laser beam transmittance.

Specific examples of the resin film include polyolefin-based films including polyethylene films, such as low density polyethylene films, linear low density polyethylene films, and high density polyethylene films, polypropylene films, polybutene films, polybutadiene films, polymethylpentene films, ethylene-norbornene copolymer films, and norbornene resin films; ethylene-based copolymer-based films, such as ethylene-vinyl acetate copolymer films, ethylene-(meth)acrylic acid copolymer films, and ethylene-(meth)acrylate copolymer films; poly (vinyl chloride)-based films, such as poly (vinylchloride) films and vinyl chloride copolymer films; polyester-based films, such as poly(ethylene terephthalate) films and poly (butylene terephthalate) films; polyurethane films; polyimide films; polystyrene films; polycarbonate films; and fluororesin films. Furthermore, a film containing a mixture of two or more types of materials, a cross-linked film obtained by cross-linking a resin forming these films, or a modified film such as an ionomer film may be used. Furthermore, the base material 120 may be a laminate film obtained by laminating two or more types of resin films.

From the viewpoint of general versatility, from the viewpoint of preventing warping because of relatively high strength, and from the viewpoint of heat resistance, the resin film can be a monolayer film selected from the group consisting of a polyethylene film, a polyester-based film, and a polypropylene film, or can be a laminate film obtained by laminating two or more types of films selected from this group.

From the viewpoint of providing supportability and roll winding properties in a compatible manner, the thickness of the base material 120 can be, but not particularly limited to, preferably 10 μm or greater, more preferably 25 μm or greater, and even more preferably 40 μm or greater, and preferably 500 μm or less, more preferably 200 μm or less, and even more preferably 90 μm or less. The range of the thickness of the base material 120 can be preferably 10 μm or greater and 500 μm or less, more preferably 25 μm or greater and 200 μm or less, and even more preferably 40 μm or greater and 90 μm or less.

### Another Layer

The pressure sensitive adhesive sheet may include a layer other than the base material 120 and the pressure sensitive adhesive layer 110. For example, an additional pressure sensitive adhesive layer may be provided on a face, which is on a side opposite to the pressure sensitive adhesive layer 110, of the base material 120. The pressure sensitive adhesive sheet may be adhered to another substrate, such as quartz glass, interposing the additional pressure sensitive adhesive layer therebetween. The type of additional pressure sensitive adhesive layer is not particularly limited, and for example, the additional pressure sensitive adhesive layer can be formed by using an ordinary adhesive agent.

### Method for Producing Pressure Sensitive Adhesive Sheet

The method for producing a pressure sensitive adhesive sheet is not particularly limited. For example, the pressure sensitive adhesive sheet, in which the pressure sensitive adhesive layer 110 is provided on the base material 120, can be produced as described below. First, an organic solvent is added to a pressure sensitive adhesive composition constituting the pressure sensitive adhesive layer 110 described above, and thus a solution of a pressure sensitive adhesive composition is prepared. After a coating film is formed by applying this solution onto a base material, the coating film is dried, and thus the pressure sensitive adhesive layer can be provided on the base material 120. Furthermore, by performing a treatment to provide unevenness on a surface of this pressure sensitive adhesive layer, a pressure sensitive adhesive layer 110 having unevenness can be formed.

Examples of the organic solvent used to prepare a solution of the pressure sensitive adhesive composition include toluene, ethyl acetate, and methyl ethyl ketone. Examples of the method of coating the solution include a spin coating method, a spray coating method, a bar coating method, a knife coating method, a roll coating method, a roll knife coating method, a blade coating method, a die coating method, a gravure coating method, and a printing method (e.g., a screen printing method and an inkjet method).

Treatment of forming unevenness on a surface of the pressure sensitive adhesive layer is not particularly limited. For example, unevenness can be provided on a surface of a pressure sensitive adhesive layer by using an imprint method. In the imprint method, a mold having a surface with a shape that is complementary to the unevenness to be provided can be used. Specifically, unevenness can be provided on a surface of the pressure sensitive adhesive layer by heating the pressure sensitive adhesive layer while the pressure sensitive adhesive layer provided on the base material is pressed with the mold. In a more specific method, a pressure sensitive adhesive layer is pressed with a mold, the pressure sensitive adhesive layer is maintained in heating for a predetermined time, then the pressure sensitive adhesive layer is cooled, and the mold can be removed. At the time of heating of the pressure sensitive adhesive layer, for example, the pressure sensitive adhesive layer can be heated to a temperature higher than the softening point of the pressure sensitive adhesive layer. Furthermore, the duration for maintaining the pressure sensitive adhesive layer in a heated condition is not particularly limited and, for example, may be 10 seconds or longer or may be 10 minutes or shorter. Examples of the specific method of heating the pressure sensitive adhesive layer while the pressure sensitive adhesive layer is pressed with a mold include a method of subjecting the pressure sensitive adhesive layer provided on the base material with a mold to vacuum-laminating. Note that, in place of performing the two step process of forming a pressure sensitive adhesive layer and forming unevenness, a pressure sensitive adhesive layer 110 having unevenness on a surface may be formed on a base material in one step process.

As another method, a pressure sensitive adhesive layer 110 having unevenness shapes can be provided by spray-coating of a solution of the pressure sensitive adhesive composition. Furthermore, by adding a filler to the solution of the pressure sensitive adhesive composition and applying this solution, a pressure sensitive adhesive layer 110 having a rough or fibrous surface can be provided. As another method, a pressure sensitive adhesive layer having unevenness shapes can be directly formed on a base material by applying a solution of a pressure sensitive adhesive composition according to a desired pattern using a printing method such as an inkjet method.

Furthermore, a pressure sensitive adhesive sheet having no base material 120 can be produced by forming a pressure sensitive adhesive composition into a sheet form. Furthermore, the pressure sensitive adhesive layer may be formed by applying a liquid pressure sensitive adhesive containing a pressure sensitive adhesive composition to a freely chosen object. In these cases, a treatment for providing unevenness on a surface of a pressure sensitive adhesive layer may be performed after a pressure sensitive adhesive layer is formed, or a pressure sensitive adhesive layer may be formed by a method, which forms unevenness on a surface.

### Method for Producing Electronic Component or Semiconductor Device Using Pressure Sensitive Adhesive Sheet According to Present Embodiment

The pressure sensitive adhesive sheet according to the present embodiment described above can be used to hold an element distant from a holding substrate. For example, a pressure sensitive adhesive sheet can be used as a die-catching sheet for catching a die, such as a semiconductor die. This element is used for producing an electronic component or a semiconductor device. That is, the pressure sensitive adhesive sheet described above can be used in production of an electronic component or a semiconductor device.

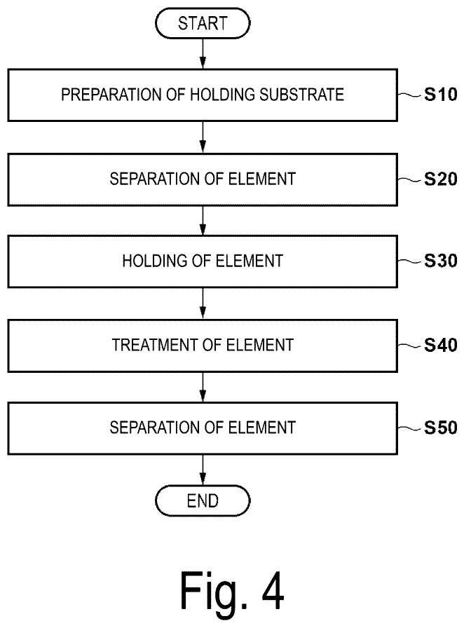

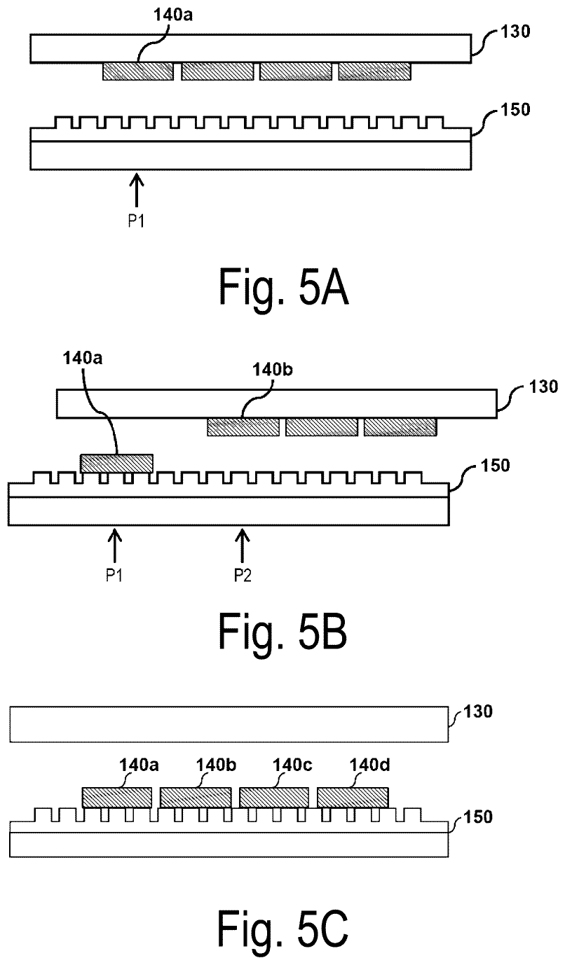

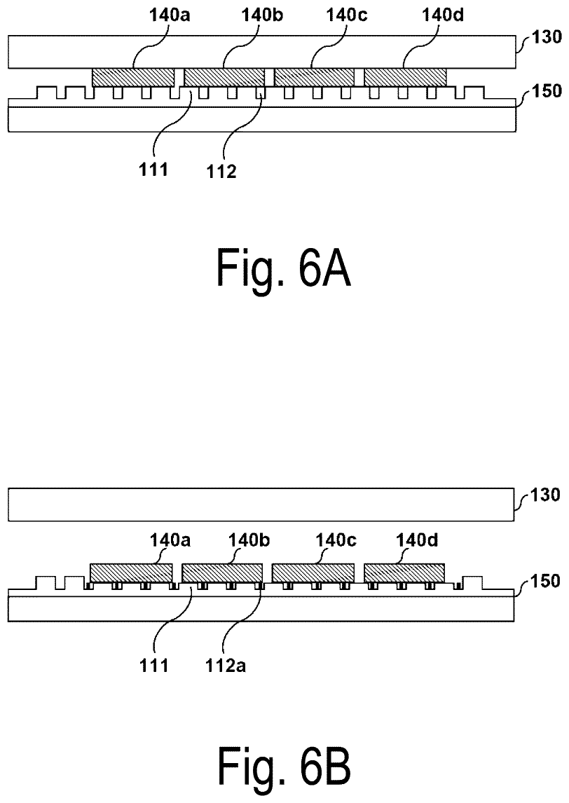

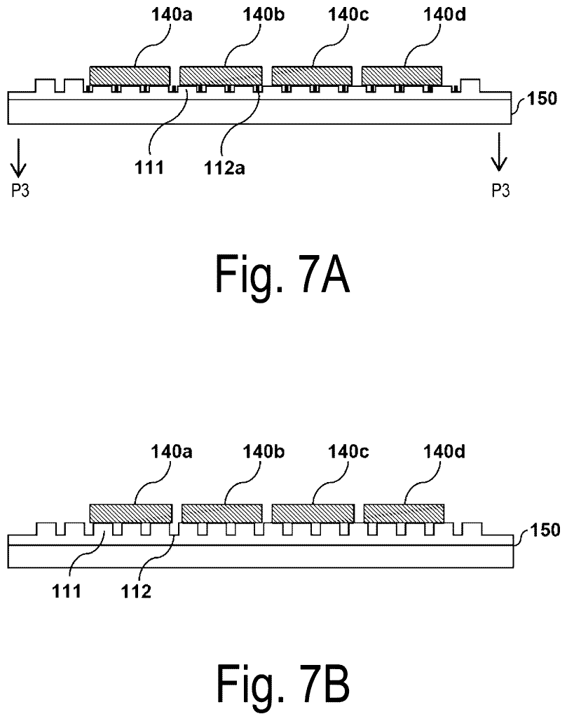

The method for producing an electronic component or a semiconductor device according to the present embodiment includes: separating an element from a holding substrate; allowing a pressure sensitive adhesive sheet to hold the element by allowing the protruded portion of the pressure sensitive adhesive layer to be deformed; and promoting separation of the element from the pressure sensitive adhesive sheet by allowing the protruded portions to recover protruded shapes. Furthermore, an electronic component or a semiconductor device may be produced by subjecting the element held on the pressure sensitive adhesive sheet to further treatment. The method for producing an electronic component or a semiconductor device will be described in detail below with reference to a flow chart of FIG. 4, schematic views explaining separation and catching of elements of FIG. 5A to FIG. 5C, schematic views explaining holding of elements of FIG. 6A and FIG. 6B, and schematic views explaining recovery of protruded portions of FIG. 7A and FIG. 7B.

### S10: Preparation of Holding Substrate

In the step S10 illustrated in FIG. 4, a holding substrate to which an element is adhered is prepared. The type of element is not particularly limited. Examples of the element include a semiconductor chip such as an LED chip, a semiconductor chip with a protective film, and a semiconductor chip with a die attach film (DAF). Furthermore, the element may be a micro LED, a mini LED, a power device, micro-electromechanical systems (MEMS), or a controller chip, or may be a component of these. Furthermore, the element may be a wafer, a panel, or a singulated material of substrate or the like. The element may have a circuit surface on which an integrated circuit having a circuit element such as a transistor, a resistor, and a capacitor is formed. Furthermore, an element is not necessarily limited to a singulated material and may be various wafers or various substrates that have not been singulated or the like.

The size of the element is not particularly limited. The size of the element may be, for example, preferably 100 μm² or greater, more preferably 500 μm² or greater, and even more preferably 1000 μm² or greater. Meanwhile, the size of the element is preferably 100 mm² or less, more preferably 25 mm² or less, and even more preferably 1 mm² or less. When an element having a small size is used, from the viewpoint of ease in selectively separating a small element, the laser lift-off method described below is suitable for separating the element.

Examples of the wafer include semiconductor wafers such as a silicon wafer, a silicon carbide (SiC) wafer, and a compound semiconductor wafer (e.g., a gallium phosphide (GaP) wafer, a gallium arsenide (GaAs) wafer, an indium phosphide (InP) wafer, and a gallium nitride (GaN) wafer). The size of the wafer is not particularly limited and is preferably 6 inches (diameter: approximately 150 mm) or greater, and more preferably 12 inches (diameter: approximately 300 mm) or greater. Note that a shape of the wafer is not limited to a circle and may be, for example, a quadrangle shape, such as a square or a rectangle.

Examples of the panel include a fan-out semiconductor package (e.g., FOWLP or FOPLP). That is, an object to be processed may be a semiconductor package before singulation or after singulation in the fan-out semiconductor package production technique. The size of the panel is not particularly limited and, for example, may be a rectangular substrate having a size of approximately 300 to 700 mm.

Examples of the substrate include a glass substrate, a sapphire substrate, or a compound semiconductor substrate.

The type of holding substrate is also not particularly limited. For example, the holding substrate may be a pressure sensitive adhesive sheet or tray. The pressure sensitive adhesive sheet may include a pressure sensitive adhesive layer, and this pressure sensitive adhesive layer may be provided on a base material. In this case, a holding substrate can hold an element on a pressure sensitive adhesive layer. The substrate may be a resin film or a hard substrate.

Such a preparation method of a holding substrate holding an element is also not particularly limited. For example, a semiconductor wafer may be adhered to a holding substrate, and then the semiconductor wafer may be diced. An element can be obtained by dicing the semiconductor wafer in this manner, and a holding substrate to which the element is adhered can be obtained.

As another method, an element obtained by dicing a semiconductor wafer is transferred to a holding substrate, and thus a holding substrate having the element adhered can be obtained. For example, a semiconductor wafer held on a wafer substrate is diced, and then the obtained element and a pressure sensitive adhesive layer of a holding substrate can be in close contact with each other. Thereafter, adhesion between the wafer substrate and the element can be reduced by providing an external stimulus such as a laser beam. By such a process, the element can be transferred from the wafer substrate to the holding substrate.

Note that, as described below, in an embodiment, the element is separated from the holding substrate by irradiation with a laser beam (laser lift-off method). In a case where such a method is used, the pressure sensitive adhesive layer of the holding substrate may contain a laser beam absorbent. Examples of the laser beam absorbent include one or more types selected from pigments and dyes.

### S20: Separation of Element

In the step S20 in FIG. 4, the element adhered to the holding substrate is separated from the holding substrate by an external stimulus. Specifically, the element is relatively distant from the holding substrate. Furthermore, the element becomes relatively closer to the pressure sensitive adhesive sheet. Due to the contact between the element and the pressure sensitive adhesive layer of the pressure sensitive adhesive sheet, the element is separated from the holding substrate and caught by the pressure sensitive adhesive sheet.

As illustrated in FIG. 5A, the position (P1) on the pressure sensitive adhesive sheet 150 is determined in a manner that the pressure sensitive adhesive sheet 150 and the element 140a adhered to the holding substrate 130 are facing, and the element 140a to be separated is transferred at the position (P1) on the pressure sensitive adhesive sheet 150. Thereafter, as illustrated in FIG. 5B, the element 140a adhered to the holding substrate 130 is separated from the holding substrate 130 by an external stimulus, and the element 140a is caught on the pressure sensitive adhesive sheet 150.

Furthermore, as illustrated in FIG. 5B, the position (P2) on the pressure sensitive adhesive sheet 150 is determined in a manner that the pressure sensitive adhesive sheet 150 and the element 140b adhered to the holding substrate 130 are facing, the element 140b to be separated is transferred at the position (P2) on the pressure sensitive adhesive sheet 150. Thereafter, similarly to the element 140a, the element 140b adhered to the holding substrate 130 is separated from the holding substrate 130 by an external stimulus, and the element 140b is caught on the pressure sensitive adhesive sheet 150.

In this way, separation and catching of the element can be performed while a relative position in a plane direction of the holding substrate and the pressure sensitive adhesive sheet is varied. Thus, the element position can be determined in a manner that a relative arrangement of a plurality of elements on the holding substrate and a relative arrangement of a plurality of elements on the pressure sensitive adhesive sheet differ.

Furthermore, in another embodiment, as illustrated in FIG. 5C, the elements 140a to 140d adhered to the holding substrate 130 are separated from the holding substrate 130 by an external stimulus without changing relative positions in a plane direction of the holding substrate and the pressure sensitive adhesive sheet, and the elements 140a to 140d are caught on the pressure sensitive adhesive sheet 150. In this case, the external stimulus may be applied successively to each of the elements or may be applied simultaneously to all the elements.

Furthermore, in a case where a pressure sensitive adhesive sheet having a flat surface is used, due to the pressure caused between the element and the pressure sensitive adhesive sheet, an element 140a in an example of FIG. 5A may be caught at a position displaced from the position (P1). However, because the surface of the pressure sensitive adhesive layer has unevenness, the pressure caused between the element and the pressure sensitive adhesive layer is relaxed, and thus catching of the element at a desired position of the pressure sensitive adhesive sheet becomes easier.

The type of external stimulus in the separation of the element is not particularly limited, and examples thereof include providing energy, cooling, stretching of the holding substrate, and physical stimulus (e.g., pressing a back face of the holding substrate by using a pin or the like). By using one or more of these external stimuli, the bonding force between the holding substrate and the element is reduced, and the element can be separated from the holding substrate.

Examples of the method of providing energy include local heating, light irradiation, and heat irradiation. Furthermore, examples of the method of light irradiation include infrared irradiation, visible light irradiation, and laser beam irradiation. In an embodiment, a laser beam irradiation is performed as the external stimulus, that is, the separation of the element from the holding substrate is performed by the laser lift-off method. In this case, the laser beam is irradiated toward the adhered portion of a specific element on the holding substrate. For example, such laser beam irradiation can be performed from a face of a side opposite to the element of the holding substrate. A gas is generated at a contact portion between the specific element and the holding substrate. For example, when the laser beam is absorbed to the pressure sensitive adhesive layer, a gas is generated by sublimation of at least a part of the pressure sensitive adhesive layer. Due to the sublimation of at least a part of the pressure sensitive adhesive layer as described above, the adhesion area between the specific element and the pressure sensitive adhesive layer decreases, and thus the adhesive strength between the specific element and the holding substrate decreases. Furthermore, also due to the pressure of the generated gas, the adhesive strength between the specific element and the holding substrate decreases. As a result, the specific element is separated from the holding substrate.

The irradiation conditions of the laser beam are not particularly limited. From the viewpoint of selectively and efficiently separate some elements, the frequency of the laser beam is preferably 10000 Hz or greater and 100000 Hz or less. Furthermore, the beam diameter of the laser beam is preferably 10 μm or greater, and more preferably 20 μm or greater, and preferably 100 μm or less, and more preferably 40 μm or less. The output of the laser beam is preferably 0.1 W or greater and 10 W or less. The scanning speed of the laser beam is preferably 50 mm/sec or greater and 2000 mm/sec or less.

### S30: Holding of Element

In the step S30, the element separated from the holding substrate is held on the pressure sensitive adhesive sheet. FIG. 6A and FIG. 6B illustrate examples where an element is held on a pressure sensitive adhesive sheet in examples of other embodiments in which separation and catching of elements are performed without changing the relative position in a plane direction of the holding substrate and the pressure sensitive adhesive sheet illustrated in FIG. 5C. The plurality of elements 140a to 140d caught on the pressure sensitive adhesive sheet 150 illustrated in FIG. 5C are covered by the holding substrate 130 as illustrated in FIG. 6A, and the elements 140a to 140d are pressed against the pressure sensitive adhesive sheet 150. Furthermore, a member pressing the elements 140a to 140d against the pressure sensitive adhesive sheet 150 is not limited to the holding substrate 130 and may be another member and, for example, a rod-like, needle-like, spherical, or plate-like member can be used. Furthermore, such a member can be a member which presses all the elements caught on the pressure sensitive adhesive sheet 150 or may be a member which presses some of the elements. In an embodiment, a layered material in which the elements 140a to 140d are sandwiched between the pressure sensitive adhesive sheet 150 and the holding substrate 130 can be passed through a laminator at a temperature of 0° C. or higher and 80° C. or lower and a pressure of 0.1 MPa or greater and 1 MPa or less to press the elements 140a to 140d against the pressure sensitive adhesive sheet 150 or to laminate these.

By pressing the elements 140a to 140d to the pressure sensitive adhesive sheet 150, the plurality of protruded portions 111 of the pressure sensitive adhesive layer are deformed as illustrated in FIG. 6B, and the elements 140a to 140d are held on the pressure sensitive adhesive sheet 150 (pressure sensitive adhesive layer). Furthermore, as the protruded portions 111 are deformed and squashed, the adhesive layer of the recessed portion 112 rises, and the protruded portions 111 and the recessed portion 112 are brought into contact with the elements 140a to 140d. Note that, in FIG. 6B, although the risen portion 112a of the pressure sensitive adhesive layer of the recessed portion 112 is illustrated with spaces between the risen portion 112a and the protruded portions 111 for easier understanding, the protruded portions 111 and the risen portion 112a may be formed in contact with each other. By this, because the elements 140a to 140d and the pressure sensitive adhesive layer are in contact in a plane, the elements 140a to 140d are held firmly on the pressure sensitive adhesive layer.

### S40: Treatment of Element

In the step S40 illustrated in FIG. 4, a treatment for producing an electronic component or a semiconductor device is performed using the element held on the pressure sensitive adhesive sheet. The treatment for producing an electronic component or a semiconductor device is not particularly limited, and examples thereof include transferring an element held on the pressure sensitive adhesive sheet to a circuit board. This circuit board may have wiring to be connected to the elements. In this case, a position of each of the elements on the circuit board is decided in advance. Thus, in the step S20, a plurality of the elements can be caught on the pressure sensitive adhesive sheet in a manner that the arrangement matches to a relative arrangement of the plurality of the elements on the circuit board. Thereafter, the circuit board is connected to a face that is on the opposite side to the pressure sensitive adhesive sheet of the plurality of the elements. Thereafter, in the next step S50, separation of the element is promoted, and the element is separated from the pressure sensitive adhesive sheet.

### S50: Separation of Element

In the step S50 in FIG. 4, the element held on the pressure sensitive adhesive sheet is separated by an external stimulus. As illustrated in FIG. 7A, the elements 140a to 140d are held on the pressure sensitive adhesive sheet 150. By applying an external stimulus to the pressure sensitive adhesive sheet 150, the deformed or squashed plurality of protruded portions 111 are allowed to recover protruded shapes as illustrated in FIG. 7B.

The type of external stimulus in the promotion of separation of the element is not particularly limited, and external stimulus used in the step S20 can be utilized. In one embodiment, utilizing stretching of the pressure sensitive adhesive sheet as an external stimulus, recovery of the protruded shapes of the deformed or squashed plurality of protruded portions 111 can be performed. For example, in FIG. 7A, by disposing, on a base (not illustrated), a position on a side opposite to the position of the pressure sensitive adhesive layer to which an element is held and by pressing down both edges of the pressure sensitive adhesive sheet as indicated by arrows (P3) at a temperature of −20° C. or higher and 80° C. or lower, the pressure sensitive adhesive sheet 150 is stretched to recover the protruded shapes of the deformed or squashed plurality of protruded portions 111.

Furthermore, as the protruded shapes of the deformed protruded portions 111 are recovered, the risen portion 112a that have been deformed or risen recovers a recess shape, and thus the protruded portions 111 and the elements 140a to 140d become in contact at points. In other words, the elements 140a to 140d are released from the risen portion 112a. By this, the elements 140a to 140d are held weakly on the pressure sensitive adhesive layer.

Thereafter, the plurality of elements 140a to 140d are separated from the pressure sensitive adhesive sheet 150. As described above, the elements 140a to 140d are easily picked up from the pressure sensitive adhesive sheet because the elements 140a to 140d are weakly held on the pressure sensitive adhesive layer. By the procedure described above, an electronic component or a semiconductor device including an element (e.g., semiconductor element) can be produced.

### Examples

The present invention will be described in further detail below through the presentation of examples. However, the present invention is in no way limited to the examples described below. Part and % in examples are based on mass unless otherwise noted.

In Examples and Comparative Examples, the following compounds were used.

### Component (A)

Acrylic copolymer (A1): monomer ratio was 2-ethylhexylacrylate/2-hydroxyethylacrylate/acrylic acid=92.8/7.0/0.2; mass average molecular weight (Mw) was 1100000.

### Component (B)

Energy ray-curable resin (B1): product name “ARONIX M-920”, available from Toagosei Co., Ltd.

Energy ray-curable resin (B2): tricyclodecanedimethanol diacrylate

Energy ray-curable resin (B3): SBS having a vinyl group in a side chain (styrene-butadiene-styrene block copolymer having a 1,2-vinyl group in a side chain [that had a branched chain structure and that had a radial structure having a branching point as a core; number average molecular weight (Mn): 160000; mass average molecular weight (Mw): 180000; content of styrene block: 20 mass %; content of butadiene block: 80 mass %; content of constitutional unit having a 1,2-vinyl group in a side chain with respect to all constitutional units constituting the butadiene block: 42 mol %; and melt flow rate measured at a condition at a temperature of 200° C. and a load of 5 kg: 5 g/10 min])

Energy ray-curable resin (B4): PB having a vinyl group in a side chain (polybutadiene copolymer having a 1,2-vinyl group in a side chain [mass average molecular weight (Mw): 5500; glass transition temperature: −49° C.; liquid at normal temperature])

### Component (C)

Cross-linking agent (C1): isocyanurate-type polyisocyanate derived from hexamethylene diisocyanate

### Component (D)

Photopolymerization initiator (D1): 1-hydroxycyclohexyl phenyl ketone

Photopolymerization initiator (D2): 2,4,6-trimethylbenzoyl diphenylphosphine oxide

Photopolymerization initiator (D3): bis(2,4,6-trimethylbenzoyl)phenylphosphine oxide

### Component (E)

Antioxidant (E1): composition in which a hindered phenol-based antioxidant and a phosphorus-based antioxidant were mixed at a mass ratio of 1:1 Example 1

In toluene, 100 parts by mass of acrylate copolymer (A1), 5 parts by mass of energy ray-curable resin (B1), 0.1 parts by mass of cross-linking agent (C1), and 0.15 parts by mass of photopolymerization initiator (D1) were dissolved, and thus a pressure sensitive adhesive composition was prepared. This pressure sensitive adhesive composition was applied onto a release-treated face of a release sheet (product name “SP-PET382150”, available from LINTEC Corporation), the obtained coating film was dried at 100° C. for 2 minutes, and thus a pressure sensitive adhesive layer having a thickness of 25 μm was formed. On this pressure sensitive adhesive layer, a base material (ethylene-methacrylic acid copolymer film; ethylene-methacrylic acid copolymer film; acid content: 9 mass %; pearskin finish by subjecting one surface to an embossing treatment; thickness: 80 μm) was adhered, and thus a pressure sensitive adhesive sheet was prepared.

After the release sheet was released, the pressure sensitive adhesive layer of the pressure sensitive adhesive sheet was adhered to a replica mold having a recess shape formed in advance and vacuum-laminated at 60° C. for 300 seconds. Thereafter, using a UV irradiation device (available from Heraeus), irradiation with ultraviolet rays at an illuminance of 130 mW/cm² and a dose at 210 mJ/cm² was performed, and thus a pressure sensitive adhesive sheet having the unevenness shapes on the surface was prepared.

The unevenness shapes included in the pressure sensitive adhesive layer of the pressure sensitive adhesive sheet were in forms, in which pillars were arranged in grid-like fashion in the same manner as in FIG. 2A. The pitch (P) between the pillars on the pressure sensitive adhesive sheet was 20 μm. Furthermore, the height (H) of each of the pillars illustrated in FIG. 3A was 8 μm, the diameter (T) of the tip part was 8 μm, and the diameter (D) of the base part was 16 μm. Furthermore, the ratio of the area of an adhered part between the pressure sensitive adhesive layer and an element to be caught (area of a tip face of the protruded portion) to the area of the pressure sensitive adhesive sheet was approximately 12.6%. Note that, as the replica mold described above, a mold having a surface shape complementary to these unevenness shapes was used.

Examples 2 to 6 and Comparative Examples 1 and 2 Pressure sensitive adhesive sheets of Examples 2 to 6 and Comparative Examples 1 and 2 were each obtained in the same manner as in Example 1 except for changing the type of components and the blending proportions to those listed in Table 1.

### Complex Shear Elastic Modulus

A pressure sensitive adhesive layer was made of the pressure sensitive adhesive composition obtained in Example 1. Using a UV irradiation device (available from Heraeus), irradiation with ultraviolet rays at an illuminance of 130 mW/cm₂ and a dose of 210 mJ/cm² was performed, and thus a pressure sensitive adhesive layer having the thickness of 1 mm was prepared. The obtained pressure sensitive adhesive layer was punched out in a columnar shape having a diameter of 8 mm. Using a viscoelasticity measuring instrument (product name “MCR302”, available from Anton Paar), the complex shear elastic modulus G* of the pressure sensitive adhesive layer at 23° C. was measured at a temperature at the start of the test of −60° C., a temperature at the end of the test of 150° C., a temperature increase rate of 3.5° C./min, and a frequency of 1 Hz using a torsional shear method. Pressure sensitive adhesive layers were produced using curable compositions obtained in Examples 2 to 6 and Comparative Examples 1 and 2 in the same manner as in Example 1. The complex shear elastic modulus G* of each of the pressure sensitive adhesive layers of Examples 2 to 6 and Comparative Examples 1 and 2 was measured.

### Evaluation of Deformability

The pressure sensitive adhesive sheet obtained in each of Examples and Comparative Examples was cut to a size of a length of 150 mm and a width of 50 mm. The pressure sensitive adhesive layer of the pressure sensitive adhesive sheet and a mirror surface of a wafer substrate (mirror silicon wafer; 6 inches; thickness: 150 μm) were adhered and laminated at a normal temperature (23° C.), then protruded portions were observed through the substrate using a microscope, and the deformability was evaluated based on the following criteria. Note that, when a protruded portion is deformed, a recessed portion defining the boundary of the protruded portion is also deformed corresponding to the aforementioned deformation, and thus the protruded portion becomes unrecognizable.
A: The number of the unrecognizable protruded portions was 80% or greater of the total number of the protruded portions.
B: The number of the unrecognizable protruded portions was 20% or greater and less than 80% of the total number of the protruded portions.
F: The number of the unrecognizable protruded portions was less than 20% of the total number of the protruded portions.

### Evaluation of Recoverability

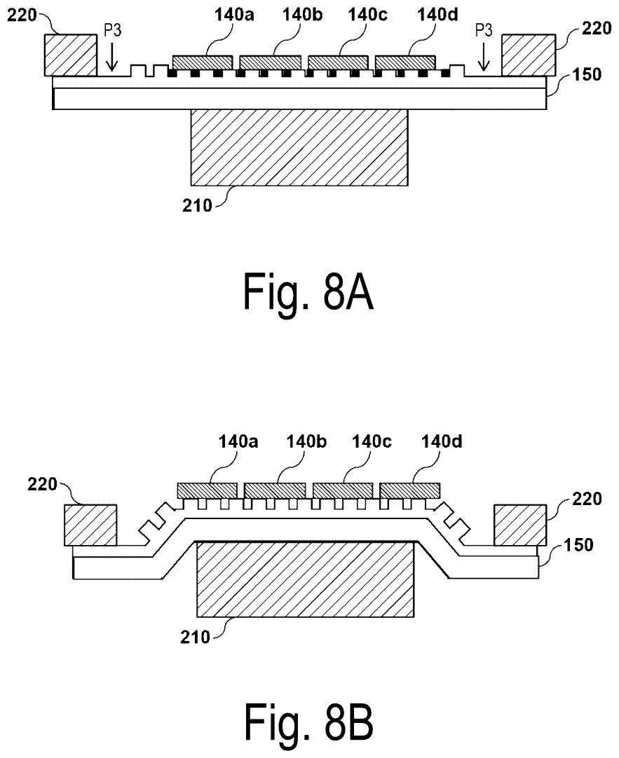

The pressure sensitive adhesive layer of the pressure sensitive adhesive sheet obtained in each of Examples was adhered to a ring frame (made of stainless steel), and the pressure sensitive adhesive sheet was cut to the outer diameter of the ring frame. A wafer substrate (mirror silicon wafer; 6 inches; thickness: 150 μm) was fixed using dicing tape separately prepared and diced to a 10 mm×10 mm square, and a plurality of elements (silicon chips; the size of each of the elements was 10 mm×10 mm×150 μm) was formed. The obtained plurality of elements was adhered to a central portion in an inner side of the ring frame of the pressure sensitive adhesive layer of the pressure sensitive adhesive sheet, and the elements were transferred from the dicing tape to the pressure sensitive adhesive sheet by releasing the dicing tape. At this time, surfaces were adjusted in a manner that the mirror surface of the silicon chip was adhered to the pressure sensitive adhesive layer of the pressure sensitive adhesive sheet, and the adhesion was performed by lamination at room temperature (23° C.). Thereafter, the pressure sensitive adhesive sheet on which the element was mounted and which was supported by the ring frame was placed on an expander having a mechanism illustrated in FIG. 8A and FIG. 8B, and the ring frame was pressed down at a speed of 1 mm/sec and an amount of pulling down of 20 mm in a condition where the element was supported by the base through the pressure sensitive adhesive sheet. After the pressing down, the protruded portions of the pressure sensitive adhesive sheet were observed through the substrate using a microscope, and the recoverability was evaluated based on the following criteria. Note that, when a protruded portion is recovered, the boundary defined by a recessed portion can be recognized, and thus the protruded portion is recognized.
A: The number of the recognizable protruded portions was 80% or greater of the total number of the protruded portions.
B: The number of the recognizable protruded portions was 20% or greater and less than 80% of the total number of the protruded portions.
F: The number of the recognizable protruded portions was less than 20% of the total number of the protruded portions.

Note that the pressure sensitive adhesive sheets of Comparative Examples 1 and 2 had evaluation results of F for the evaluation of deformability, and the protruded portion was not deformed, and thus no evaluation of recoverability was performed.

The results for complex shear elastic modulus, deformability evaluation, and recoverability evaluation of each of Examples 1 to 6 and Comparative Examples 1 and 2 are shown in Table 1.

TABLE 1

| | | | | | | | | | | | Complex | | |
|---|---|---|---|---|---|---|---|---|---|---|---|---|---|
| | | | | | | | | | | | Shear | | |
| | Component | | | | | Component | | | | Component | Elastic | | |
| | (A) | Component (B) | | | | (C) | Component (D) | | | (E) | Modulus | Deformability | Recoverability |
| | A1 | B1 | B2 | B3 | B4 | C1 | D1 | D2 | D3 | E1 | [MPa] | evaluation | evaluation |
| Example 1 | 100 | 5.0 | 0 | 0 | 0 | 0.1 | 0.150 | 0 | 0 | 0 | 0.063 | A | A |
| Example 2 | 100 | 5.0 | 0 | 0 | 0 | 0.5 | 0.150 | 0 | 0 | 0 | 0.097 | A | A |
| Example 3 | 100 | 5.0 | 0 | 0 | 0 | 1.0 | 0.150 | 0 | 0 | 0 | 0.140 | A | A |
| Example 4 | 100 | 0 | 5.0 | 0 | 0 | 0.5 | 0 | 0.150 | 0 | 0 | 0.250 | A | A |
| Example 5 | 100 | 0 | 7.5 | 0 | 0 | 0.5 | 0 | 0.225 | 0 | 0 | 0.850 | B | A |
| Example 6 | 0 | 0 | 0 | 73.5 | 23.5 | 0 | 0 | 0 | 3.000 | 3 | 0.330 | B | A |
| Comparative | 100 | 0 | 10.0 | 0 | 0 | 0.5 | 0.300 | 0 | 0 | 0 | 2.100 | F | — |
| Example 1 | | | | | | | | | | | | | |
| Comparative | 100 | 0 | 12.5 | 0 | 0 | 0.5 | 0.375 | 0 | 0 | 0 | 6.400 | F | — |
| Example 2 | | | | | | | | | | | | | |

The pressure sensitive adhesive sheet of each of Examples 1 to 6 had a complex shear elastic modulus at 23° C. of 0.001 MPa or greater and 1.0 MPa or less. In addition, the deformability of the protruded portions of the pressure sensitive adhesive sheet of each of Examples 1 to 4 was evaluated as A, the deformability of the protruded portions of the pressure sensitive adhesive sheet of each of Examples 5 and 6 was evaluated as B, and the recoverability of the protruded portions of the pressure sensitive adhesive sheet of each of Examples 1 to 6 was evaluated as A. Thus, the pressure sensitive adhesive sheets of Examples 1 to 6 were able to vary the capability of holding the elements. That is, the pressure sensitive adhesive sheets of Examples 1 to 6 can firmly hold elements by deformation and squashing of the protruded portions of the pressure sensitive adhesive sheets when the elements are held. Furthermore, since some of the pressure sensitive adhesive sheets of Examples 1 to 6 can weakly hold the elements when the protruded portions of the pressure sensitive adhesive sheets recover protruded shapes by external stimuli, the elements can be easily picked up from the pressure sensitive adhesive sheets.

On the other hand, the pressure sensitive adhesive sheet of each of Comparative Examples 1 and 2 had a complex shear elastic modulus at 23° C. of greater than 1.0 MPa. Furthermore, the deformability of the protruded portions of the pressure sensitive adhesive sheet of each of Comparative Examples 1 and 2 was evaluated as F. For the pressure sensitive adhesive sheets of Comparative Examples 1 and 2, the protruded portions of the pressure sensitive adhesive sheets did not deform when elements were held, and the elements could not be held firmly. Thus, the pressure sensitive adhesive sheets of Comparative Examples 1 and 2 were not able to vary the capability of holding the elements.

The embodiments of the present invention are described above; however, the invention is not limited by the embodiments described above, and various variation and changes can be made within the gist of the present invention.

What is claimed is:

1. A pressure sensitive adhesive sheet comprising:
a pressure sensitive adhesive layer configured to catch elements distant from a holding substrate, wherein
the pressure sensitive adhesive layer has unevenness on a surface and has a complex shear elastic modulus at 23° C. of 0.001 MPa or greater and 1.0 MPa or less.

2. The pressure sensitive adhesive sheet according to claim 1, wherein
the pressure sensitive adhesive layer has a plurality of protruded portions on a surface of the pressure sensitive adhesive layer, each of the plurality of protruded portions having a boundary defined by a recessed portion, the plurality of protruded portions being separated from each other, and
each of the plurality of protruded portions is deformed by being pressed when the element is caught, and each of the plurality of protruded portions deformed is recovered to a protruded shape by an external stimulus.

3. The pressure sensitive adhesive sheet according to claim 1, wherein
the pressure sensitive adhesive layer has a plurality of protruded portions on a surface of the pressure sensitive adhesive layer, each of the plurality of protruded portions having a boundary defined by a recessed portion, and the plurality of protruded portions being separated from each other, and
a height of each of the plurality of protruded portions is 1 μm or greater.

4. The pressure sensitive adhesive sheet according to claim 1, wherein the pressure sensitive adhesive layer is made of a pressure sensitive adhesive composition containing an energy ray-curable compound (B).

5. The pressure sensitive adhesive sheet according to claim 1, wherein the pressure sensitive adhesive layer is made of a pressure sensitive adhesive composition containing an acrylic resin (A).

6. The pressure sensitive adhesive sheet according to claim 1, wherein the pressure sensitive adhesive layer is made of a pressure sensitive adhesive composition containing an acrylic resin (A) and an energy ray-curable compound (B).

7. The pressure sensitive adhesive sheet according to claim 1, wherein
the pressure sensitive adhesive layer has a plurality of protruded portions on a surface of the pressure sensitive adhesive layer, each of the plurality of protruded portions having a boundary defined by a recessed portion, the plurality of protruded portions being separated from each other, and
a pitch of the plurality of protruded portions is 1 μm or greater and 100 μm or less.

8. The pressure sensitive adhesive sheet according to claim 1, wherein
the pressure sensitive adhesive layer has a plurality of protruded portions on a surface of the pressure sensitive adhesive layer, each of the plurality of protruded portions having a boundary defined by a recessed portion, and the plurality of protruded portions being separated from each other, and
an area of each of the plurality of protruded portions is 10 μm² or greater and 2000 μm² or less.

9. The pressure sensitive adhesive sheet according to claim 1, wherein
the pressure sensitive adhesive layer has a plurality of protruded portions on a surface of the pressure sensitive adhesive layer, each of the plurality of protruded portions having a boundary defined by a recessed portion, the plurality of protruded portions being separated from each other, and
a ratio of an area of the protruded portion to an area of the pressure sensitive adhesive layer is 1% or greater and 95% or less.

10. The pressure sensitive adhesive sheet according to claim 1, wherein the pressure sensitive adhesive layer has a ratio of an adhesion area of the pressure sensitive adhesive layer and one of the elements to an area of the one of the elements of 1% or greater and 95% or less.

11. A method for producing an electronic component or a semiconductor device, the method comprising:
separating an element adhered to a holding substrate from the holding substrate by an external stimulus;
allowing a pressure sensitive adhesive layer to hold the element by pressing the element separated from the holding substrate against a pressure sensitive adhesive sheet and deforming a plurality of protruded portions on a surface of the pressure sensitive adhesive layer, wherein the pressure sensitive adhesive sheet comprises the pressure sensitive adhesive layer configured to catch elements distant from the holding substrate, the pressure sensitive adhesive layer has unevenness on the surface and has a complex shear elastic modulus at 23° C. of 0.001 MPa or greater and 1.0 MPa or less, each of the plurality of protruded portions has a boundary defined by a recessed portion, and the plurality of protruded portions are separated from each other; and
promoting separation of the element from the pressure sensitive adhesive sheet by allowing the plurality of protruded portions deformed to be recovered to a protruded shape by an external stimulus.
